(19) United States
(12) Patent Application Publication
(10) Pub. No.: US 2011/0114113 A1
(43) Pub. Date: May 19, 2011

(54) SUBSTRATE PROCESSING APPARATUS, CLEANING METHOD THEREOF AND STORAGE MEDIUM STORING PROGRAM

(75) Inventors: Masanobu Honda, Yamanashi (JP); Takahiro Murakami, Yamanashi (JP); Takanori Mimura, Yamanashi (JP); Hidetoshi Hanaoka, Yamanashi (JP)

(73) Assignee: TOKYO ELECTRON LIMITED, Tokyo (JP)

(21) Appl. No.: 12/948,307

(22) Filed: Nov. 17, 2010

Related U.S. Application Data
(60) Provisional application No. 61/296,307, filed on Jan. 19, 2010.

(30) Foreign Application Priority Data
Nov. 18, 2009 (JP) 2009-263069

(51) Int. Cl. B08B 7/00; H01L 21/3065

(52) U.S. Cl. 134/1.1; 156/345.26

(57) ABSTRACT

There is provided a cleaning method for a substrate processing apparatus capable of improving a removing rate of a deposit without increasing a self-bias voltage. The cleaning method includes supplying, to clean the inside of a processing chamber 102 under preset processing conditions, a processing gas including an O₂ gas and an inert gas into the processing chamber at a preset flow rate ratio of the processing gas; and generating plasma of the processing gas by applying a high frequency power between a lower electrode 111 and a upper electrode 120. Here, the preset flow rate ratio of the processing gas is set depending on a self-bias voltage of the lower electrode 111 such that a flow rate ratio of the O₂ gas is reduced while a flow rate ratio of the Ar gas is increased as an absolute value of the self-bias voltage decreases.

### CROSS-REFERENCE TO RELATED APPLICATION

This application claims the benefit of Japanese Patent Application No. 2009-263069 filed on Nov. 18, 2009 and U.S. Provisional Application Ser. No. 61/296,307 filed on Jan. 19, 2010, the entire disclosures of which are incorporated herein by reference.

### FIELD OF THE INVENTION

The present disclosure relates to a substrate processing apparatus for cleaning the inside of a processing chamber having therein a mounting table for mounting thereon a substrate such as a semiconductor wafer or a FPD substrate and also relates to a cleaning method of the substrate processing apparatus and a storage medium storing a program.

### BACKGROUND OF THE INVENTION

A substrate processing apparatus for manufacturing a semiconductor device includes a processing chamber, and the processing chamber includes a mounting table for mounting thereon a substrate such as a semiconductor wafer or a liquid crystal display (LCD) substrate and serving as a lower electrode; and an upper electrode installed so as to face the mounting table. When a plasma process such as etching or film formation is performed in this substrate processing apparatus, a substrate is attracted to and held on an electrostatic chuck on the mounting table, and a processing gas is introduced into the processing chamber. Then, plasma of the processing gas is generated between the upper and lower electrodes, and the plasma process on the substrate is performed by the plasma.

In such a plasma processing apparatus, it is important to remove reaction products generated when the substrate is processed in the processing chamber or to remove fine particles (foreign substances in the form of fine particles) introduced into the processing chamber from the outside.

By way of example, since particles reach even a rear surface of the substrate, the particles may be adhered to the mounting table on which the substrate is mounted. Especially, the particles may be easily adhered to a periphery of the mounting table. If these particles are not removed, deposits (e.g., a CF polymer) may be deposited on the mounting table as the plasma process is repeated, resulting in reduction of an attracting force for attracting and holding the substrate onto the mounting table or resulting in a position deviation of the substrate when the substrate is mounted on the mounting table by a transfer arm.

Further, if particles are adhered to a rear surface of the substrate mounted on the mounting table, another problem may be caused in a next process. Furthermore, if particles remain in the processing chamber, the particles may be adhered to a next substrate to be processed, adversely affecting the process performed on the next substrate and thus resulting in a failure to obtain a good quality of a semiconductor device finally formed on the substrate.

By way of example, as a way to remove particles in the processing chamber effectively, Patent Document 1 discloses a cleaning method for removing deposits from a mounting table. In this cleaning method, plasma and radicals are generated by introducing an O₂ gas into a processing chamber after a substrate is separated from the mounting table, and the deposits are removed from the mounting table by a chemical reaction between the radicals and the deposits adhered to the mounting table. Further, Patent Documents 3 to 4 also disclose cleaning methods for removing particles in a processing chamber by radicals or ions generated by exciting a rare gas containing an oxide such as oxygen into plasma.

Patent Document 1: Japanese Patent Laid-open Publication No. 2006-19626

Patent Document 2: Japanese Patent Laid-open Publication No. H8-97189

Patent Document 3: Japanese Patent Laid-open Publication No. 2005-142198

Patent Document 4: Japanese Patent Laid-open Publication No. 2009-65170

Since, however, deposits composed of particles on the mounting table (or lower electrode serving as a mounting table) may form a polymer (e.g., a CF polymer), it takes time to remove the deposits even if cleaning is performed by using plasma excited from the O₂ gas as stated above.

To improve a removing rate of the deposits, it may be attempted to increase the energy of the radicals or ions by increasing a self-bias voltage of the lower electrode by increasing a high frequency power applied to the electrode or by reducing an internal pressure of the processing chamber as low as possible.

However, since a surface of the mounting table is exposed to the plasma in a wafer-less cleaning process in which cleaning is performed without mounting a substrate on the mounting table, ion impact or the like may increase as the self-bias voltage of the lower electrode increases, rendering the surface of the mounting table liable to be damaged.

### BRIEF SUMMARY OF THE INVENTION

In view of the foregoing, the present disclosure provides a cleaning method capable of improving a removing rate of a deposit without increasing a self-bias voltage.

Generally, when a gaseous mixture of an O₂ gas and an inert gas is used to clean the inside of the processing chamber, it has been expected that a removing rate of deposits would be reduced as a flow rate ratio of the inert gas is increased because a partial pressure of the O₂ gas would be reduced with the rise of the inert gas. However, the present inventors conducted actual experiments under a condition where an internal pressure of the processing chamber is low or under a condition where a first high frequency power and a second high frequency power are low (e.g., a self-bias voltage of the lower electrode is equal to or less than about 50 V or equal to or less than about 160 V). That is, the experiments were conducted under a condition where ion energy is low. To the contrary to the conventional expectation, when the inert gas was increased so as to reduce a flow rate ratio of the O₂ gas, there was found a flow rate ratio range in which a removing rate of deposits increased. The present disclosure to be described below has been conceived from such a finding.

In accordance with one aspect of the present disclosure, there is provided a cleaning method for a substrate processing apparatus for cleaning the inside of an evacuable processing chamber including an upper electrode and a substrate mounting table having a lower electrode installed so as to face the upper electrode. The cleaning method includes supplying, to clean the inside of the processing chamber under preset processing conditions, a processing gas including an O₂ gas and an inert gas into the processing chamber at a preset flow rate ratio of the processing gas; and generating plasma of the processing gas by applying a high frequency power between the electrodes. Here, the flow rate ratio of the processing gas is set depending on a self-bias voltage of the lower electrode such that a flow rate ratio of the O₂ gas is reduced while a flow rate ratio of the inert gas is increased as an absolute value of the self-bias voltage decreases.

In accordance with another aspect of the present disclosure, there is provided a substrate processing apparatus including an evacuable processing chamber; an upper electrode and a lower electrode installed in the processing chamber so as to face each other; a substrate mounting table including the lower electrode; a power supply unit that supplies a preset high frequency power between the electrodes; a gas supply unit that supplies an O₂ gas and an inert gas into the processing chamber as a processing gas for cleaning; a gas exhaust unit that evacuates the processing chamber and depressurizes the inside of the processing chamber to a preset pressure; a storage unit that stores therein a flow rate ratio of the processing gas set depending on a self-bias voltage of the lower electrode such that a flow rate ratio of the O₂ gas is reduced while a flow rate ratio of the inert gas is increased as an absolute value of the self-bias voltage decreases when the inside of the processing chamber is cleaned under preset processing conditions; and a controller that reads out the flow rate ratio corresponding to a self-bias voltage from the storage unit when the inside of the processing chamber is cleaned, supplies the O₂ gas and the inert gas from the gas supply unit at the read-out flow rate ratio and generates plasma by applying a preset high frequency power between the electrodes from the power supply unit.

In accordance with still another aspect of the present disclosure, there is provided a computer readable storage medium that stores therein a program for implementing the cleaning method.

In the cleaning method and the substrate processing apparatus, the inert gas may be, by way of example, an Ar gas. Further, desirably, the flow rate ratio of the O₂ gas and the inert gas may be set such that the flow rate ratio of the O₂ gas is equal to or higher than about 8% and less than about 33% of the entire processing gas when the cleaning is performed under a processing condition that the absolute value of the self-bias voltage is equal to or less than about 50 V.

Further, the flow rate ratio of the O₂ gas and the inert gas may be set such that the flow rate ratio of the O₂ gas is equal to or higher than about 33% and less than about 100% of the entire processing gas when the cleaning is performed under a processing condition that the absolute value of the self-bias voltage is more than about 50 V and less than about 160 V.

Here, in the present specification, 1 mTorr is about (10⁻³×101325/760) Pa, and 1 sccm is about (10⁻⁶/60) m³/sec.

In accordance with the present disclosure, by setting the flow rate ratio of the O₂ gas to decrease while the flow rate ratio of the Ar gas increases depending on the self-bias voltage of the lower electrode, a removing rate of the deposit can be increased without increasing the self-bias voltage. Accordingly, time taken to remove the deposits can be shortened while damage on the surface of the mounting table is suppressed.

### BRIEF DESCRIPTION OF THE DRAWINGS

Non-limiting and non-exhaustive embodiments will be described in conjunction with the accompanying drawings. Understanding that these drawings depict only several embodiments in accordance with the disclosure and are, therefore, not to be intended to limit its scope, the disclosure will be described with specificity and detail through use of the accompanying drawings, in which:

FIG. 1 is a cross sectional view illustrating a plasma processing apparatus in accordance with an embodiment of the present disclosure;

FIG. 2 is an enlarged view of a mounting table shown in FIG. 1;

FIG. 3A is a graph showing a relationship between a flow rate ratio of a processing gas and a removing rate when an internal pressure of a processing chamber is set to about 100 mTorr;

FIG. 3B is a graph showing a relationship between a flow rate ratio of the processing gas and a removing rate when the internal pressure of the processing chamber is set to about 200 mTorr;

FIG. 3C is a graph showing a relationship between a flow rate ratio of the processing gas and a removing rate when the internal pressure of the processing chamber is set to about 400 mTorr;

FIG. 3D is a graph showing a relationship between a flow rate ratio of the processing gas and a removing rate when the internal pressure of the processing chamber is set to about 750 mTorr;

FIG. 4A is a graph in which a vertical axis indicates a removing rate at an edge of a wafer W of FIGS. 3A to 3D and a horizontal axis indicates a flow rate ratio of the processing gas;

FIG. 4B is a graph in which a removing rate at each flow rate ratio is standardized by a removing rate obtained when a flow rate ratio of an Ar gas is 0 (i.e., O₂ gas is 100%) in FIG. 4A;

FIG. 5A is a graph showing a relationship between a flow rate ratio of the processing gas and a removing rate when a level of a first high frequency power is changed and an internal pressure of the processing chamber is maintained at about 100 mTorr;

FIG. 5B is a graph in which a removing rate at each flow rate ratio is standardized by a removing rate obtained when a flow rate ratio of the Ar gas is 0 (i.e., O₂ gas is 100%) in FIG. 5A;

FIG. 6A is a graph showing a relationship between a flow rate ratio of the processing gas and a removing rate when a level of a second high frequency power is changed and an internal pressure of the processing chamber is maintained at about 400 mTorr;

FIG. 6B is a graph in which a removing rate at each flow rate ratio is standardized by a removing rate obtained when a flow rate ratio of the Ar gas is 0 (i.e., O₂ gas is 100%) in FIG. 6A;

FIG. 7A is a graph showing a relationship between a flow rate ratio of the processing gas and a removing rate when a level of the second high frequency power is changed and the internal pressure of the processing chamber is maintained at about 100 mTorr;

FIG. 7B is a graph in which a removing rate at each flow rate ratio is standardized by a removing rate obtained when a flow rate ratio of the Ar gas is 0 (i.e., O₂ gas is 100%) in FIG. 5A; and

FIG. 8 is a graph showing a relationship between an absolute value of a self-bias voltage and a removing rate.

### DETAILED DESCRIPTION OF THE INVENTION

Hereinafter, embodiments of the present disclosure will be explained in detail with reference to accompanying drawings. Through the present specification and drawings, parts having substantially same function and configuration will be assigned same reference numerals, and redundant description will be omitted.

(Configuration Example of a Substrate Processing Apparatus)

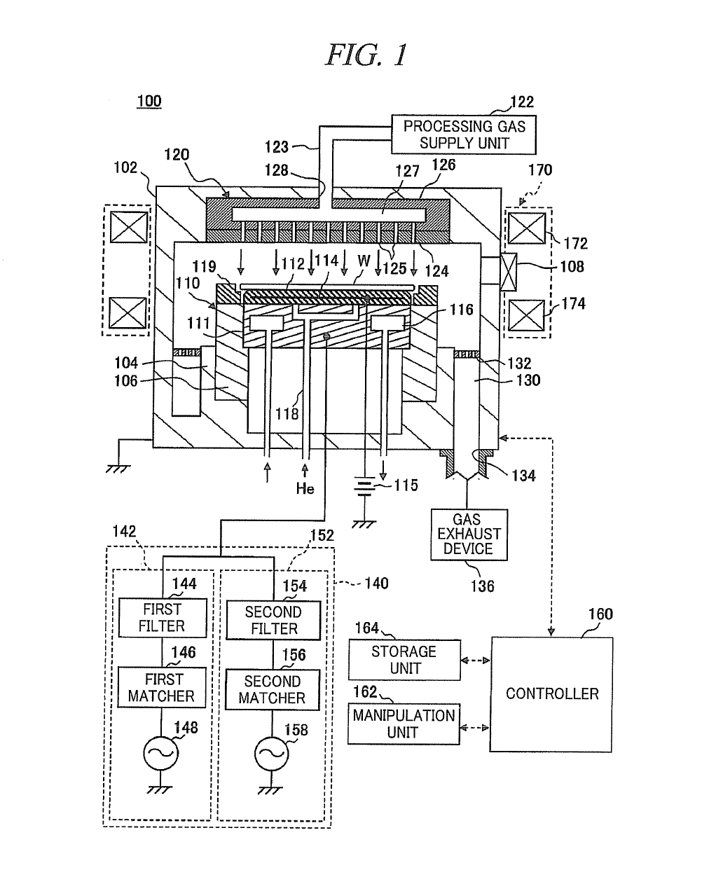

Above all, a configuration example of a substrate processing apparatus in accordance with an embodiment of the present disclosure will be explained with reference to the drawings. Herein, there will be explained a substrate processing apparatus configured as a plasma processing apparatus in which an etching target film on a wafer W is etched by applying a first high frequency power (high frequency power for plasma generation) of a relatively high frequency of, e.g., about 40 MHz and a second high frequency power (high frequency power for a bias voltage) of a relatively low frequency of, e.g., about 13.56 MHz to a single electrode (lower electrode) serving as a mounting table. FIG. 1 is a cross sectional view showing a schematic configuration of a plasma processing apparatus in accordance with the present embodiment.

As illustrated in FIG. 1, the plasma processing apparatus 100 may include a processing chamber 102 having a cylinder-shaped processing vessel made of metal such as aluminum or stainless steel of which a surface is anodically oxidized (alumite treated). The processing chamber 102 is grounded. In the processing chamber 102, there is provided a substrate mounting table (hereinafter, simply referred to as “mounting table”) 110 for mounting a substrate such as a semiconductor wafer W (hereinafter, simply referred to as “wafer”). The mounting table 110 may include a circular plate-shaped lower electrode (a susceptor) 111 and an upper electrode 120 also serving as a shower head positioned above the lower electrode 111 to face the lower electrode 111 and supply a processing gas or a purge gas.

The lower electrode 111 is made of, for example, aluminum. The lower electrode 111 is held on an insulating cylindrical holder 106 on a cylindrical member 104 extended in a vertically upward direction from a bottom of the processing chamber 102. On a top surface of the lower electrode 111, an electrostatic chuck 112 for holding the wafer W by an electrostatic attracting force is installed. The electrostatic chuck 112 may include an electrostatic chuck electrode 114 made of, for example, a conductive film embedded in an insulating film. The electrostatic chuck electrode 114 is electrically connected with a DC power supply 115. With this configuration of the electrostatic chuck 112, the wafer W can be attracted to and held on the electrostatic chuck 112 by a Coulomb force caused by a DC voltage from the DC power supply 115.

Installed within the lower electrode 111 is a cooling unit. By way of example, this cooling unit is configured to circulate and supply a coolant (for example, cooling water) at a predetermined temperature to a cooling reservoir 116 extended in a circumferential direction in the lower electrode 111 from a non-illustrated chiller unit through a coolant line. A processing temperature of the wafer W on the electrostatic chuck 112 can be controlled by the coolant.

In the lower electrode 111 and the electrostatic chuck 112, a heat transfer gas supply line 118 is provided toward a rear surface of the wafer W. A heat transfer gas (a backgas) such as a He gas is introduced through the heat transfer gas supply line 118 and supplied between a top surface of the electrostatic chuck 112 and the rear surface of the wafer W. Accordingly, a heat transfer between the lower electrode 111 and the wafer W is accelerated. A focus ring 119 is installed so as to surround the wafer W mounted on the electrostatic chuck 112. The focus ring 119 is made of, for example, quartz or silicon and installed on a top surface of the cylindrical holder 106.

The upper electrode 120 is provided at a ceiling of the processing chamber 102. The upper electrode 120 is grounded. The upper electrode 120 is connected with a processing gas supply unit 122 which supplies a gas required for a process in the processing chamber 102 via a gas line 123. By way of example, the processing gas supply unit 122 may include a gas supply source which supplies a processing gas or a purge gas required for a process performed on a wafer or a cleaning process in the processing chamber 102, a valve and a mass flow controller which control introduction of a gas from the gas supply source.

The upper electrode 120 may include an electrode plate 124 having a plurality of gas vent holes 125 at a bottom surface and an electrode support 126 which supports the electrode plate 124 detachably attached thereto. Provided within the electrode support 126 is a buffer room 127. A gas inlet 128 of this buffer room 127 is connected with the gas line 123 of the processing gas supply unit 122.

FIG. 1 illustrates an example case where the processing gas supply unit 122 supplies a single processing gas through a single gas line, but the present disclosure is not limited thereto. By way of example, the present disclosure can be applied to a case where the processing gas supply unit 122 provides a plurality of processing gases. In this case, the plasma processing apparatus 100 may be provided with a plurality of gas supply sources, the processing gas supply unit 122 may provide a plurality of gases through a plurality of gas lines, and mass flow controllers may be provided on the respective gas lines.

By way of example, a halogen-based gas such as a Cl gas may be used as a processing gas supplied into the processing chamber 102 from the processing gas supply unit 122 to etch an oxide film. To elaborate, a CHF₃ gas may be used as a processing gas to etch a silicon oxide film such as a SiO₂ film. Further, a BCl₃ gas or a gaseous mixture of a BCl₃ gas and an O₂ gas may be used as a processing gas to etch a high-k thin film such as HfO₂, HfSiO₂, ZrO₂ and ZrSiO₄. Furthermore, a gaseous mixture of a HBr gas and an O₂ gas may be used as a processing gas to etch a polysilicon film.

Further, an O₂ gas or a gaseous mixture of an O₂ gas and an inert gas (e.g., an Ar gas or a He gas) may be used to clean the inside of the processing chamber 102. As a cleaning process of the present disclosure, there will be explained an example case where a gaseous mixture of an O₂ gas and an Ar gas is used as a processing gas.

Formed between a sidewall of the processing chamber 102 and the cylindrical member 104 is a gas exhaust path 130. A ring-shaped baffle plate 132 is positioned at an entrance of the gas exhaust path 130 or on its way, and a gas exhaust port 134 is provided at a bottom portion of the gas exhaust path 130. The gas exhaust port 134 is connected with a gas exhaust device 136 via a gas exhaust pipe. The gas exhaust device 136 includes, for example, a vacuum pump and is configured to depressurize the inside of the processing chamber 102 to a certain vacuum level. Further, installed at the sidewall of the processing chamber 102 is a gate valve 108 which opens and closes a loading/unloading port for the wafer W.

The lower electrode 111 is connected with a power supply device 140 which supplies dual frequency powers thereto. The power supply device 140 may include a first high frequency power supply unit 142 which supplies a first high frequency power (high frequency power for generating plasma) of a first frequency and a second high frequency power supply unit 152 which supplies a second high frequency power (high frequency power for generating a bias voltage) of a second frequency lower than the first frequency.

The first high frequency power supply unit 142 may include a first filter 144, a first matcher 146, and a first power supply 148 connected to the lower electrode 111 in sequence. The first filter 144 prevents the second frequency power from entering into the first matcher 146. The first matcher 146 matches the first high frequency power.

The second high frequency power supply unit 152 may include a second filter 154, a second matcher 156, and a second power supply 158 connected to the lower electrode 111 in sequence. The second filter 154 prevents the first frequency power from entering into the second matcher 156. The second matcher 156 matches the second high frequency power.

A magnetic field generation unit 170 is provided so as to surround the processing chamber 102. The magnetic field generation unit 170 may include an upper magnet ring 172 and a lower magnet ring 174 vertically spaced from each other and arranged along a circumference of the processing chamber 102. The magnetic field generation unit 170 generates a cusp magnetic field which surrounds a plasma processing space in the processing chamber 102.

The plasma processing apparatus 100 is connected with a controller (an overall control device) 160, and each component of the plasma processing apparatus 100 is controlled by this controller 160. Further, the controller 160 is connected with a manipulation unit 162 including a keyboard through which an operator inputs commands to manage the plasma processing apparatus 100 or a display which visually displays an operation status of the plasma processing apparatus 100.

Furthermore, the controller 160 is connected with a storage unit 164 that stores therein: programs for implementing various processes (e.g., a plasma process on the wafer W) performed in the plasma processing apparatus 100 under the control of the controller 160; and processing conditions (recipes) required for executing the programs.

By way of example, the storage unit 164 stores a plurality of processing conditions (recipes). Each processing condition includes a plurality of parameter values such as control parameters controlling each component of the plasma processing apparatus 100 and setting parameters. By way of example, each processing condition may include parameter values such as a flow rate ratio of processing gases, a pressure in a processing chamber, and a high frequency power value.

Moreover, the programs or processing conditions may be stored in a hard disc or a semiconductor memory, or may be set in a predetermined area of the storage unit 164 in the form of a storage medium readable by a portable computer such as a CD-ROM or a DVD.

The controller 160 reads out a program and processing condition from the storage unit 164 in response to an instruction from the manipulation unit 162 and controls each component, thereby carrying out a desired process in the plasma processing apparatus 100. Further, the processing condition can be edited by the manipulation unit 162.

(Operation of the Plasma Processing Apparatus)

Now, an operation of the plasma processing apparatus 100 will be described. By way of example, in order to perform a plasma process on a wafer W, the wafer W to be processed is loaded into the processing chamber 102 through the gate valve 108 by a non-illustrated transfer arm. If the wafer W is mounted on the mounting table 110, i.e., on the electrostatic chuck 112, the DC power supply 115 is turned on, and the wafer W is firmly attracted and held on the electrostatic chuck 112. Then, the plasma process is begun.

The plasma etching process is performed based on preset processing conditions (recipes). To elaborate, the inside of the processing chamber 102 is depressurized to a preset pressure, and processing gases (e.g., a gaseous mixture including a C₄F₈ gas, an O₂ gas and an Ar gas) are introduced into the processing chamber 102 at preset flow rates and at a preset flow rate ratio from the upper electrode 120.

In this state, a first high frequency power equal to or higher than about 10 MHz, e.g., about 100 MHz, is applied to the lower electrode 111 from the first high frequency power supply 148, and a second high frequency power equal to or higher than about 2 MHz and less than about 10 MHz, e.g., about 3 MHz, is applied to the lower electrode 111 from the second high frequency power supply 158. Accordingly, plasma of the processing gases is generated between the lower electrode 111 and the upper electrode 120 by the first high frequency power, and a self-bias voltage (−Vdc) is generated in the lower electrode 111 by the second high frequency power, so that the plasma process on the wafer W can be carried out. In this way, by applying both the first high frequency power and the second high frequency power to the lower electrode 111, the plasma can be appropriately controlled, and, thus, effective plasma process can be carried out.

Upon the completion of the plasma process, the attracting force of the electrostatic chuck 112 is removed by turning off the DC power supply 115, and the wafer W is unloaded through the gate valve 108 by the non-illustrated transfer arm.

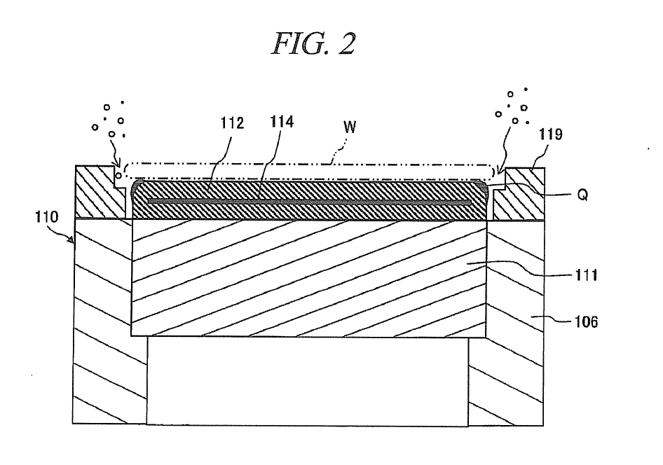

If the above-described plasma etching of the wafer W is performed, particles such as reaction products by the plasma process may be generated in the processing chamber 102. These particles may be adhered to the mounting table 110 or the like provided in the processing chamber 102 as well as on an inner sidewall of the processing chamber 102. By way of example, the particles may enter a gap between the wafer W and the focus ring 119 and may be adhered to a top of a periphery of the electrostatic chuck 112, as illustrated in FIG. 2.

If such deposits (e.g., a CF polymer) composed of the particles are not removed, the deposit may be deposited every time the plasma etching process is repeated. As a result, an attracting force for the wafer W would be reduced or a position deviation of the wafer W may be caused when the wafer W is mounted on the electrostatic chuck 112. Further, if a part of the deposits is detached and floats within the processing chamber, the deposits may be adhered to the wafer W. If the deposits are adhered to the wafer W, a short circuit of wiring of a semiconductor device formed on the wafer W may be caused, resulting in reduction of a yield.

Thus, in the plasma processing apparatus 100, a cleaning process for cleaning the inside of the processing chamber 102 is regularly performed at a preset timing. By way of example, the cleaning process may be performed whenever a plasma etching process of a single wafer W is completed or whenever plasma etching processes for one lot (e.g., 25 sheets) of wafers W are completed.

In the cleaning process, a processing gas for cleaning is introduced into the processing chamber 102 and the inside of the processing chamber 102 is maintained at a preset pressure. In this state, a first high frequency power equal to or higher than about 10 MHz, e.g., about 100 MHz, is supplied from the first power supply 148 to the lower electrode 111, and a second high frequency power equal to or higher than about 2 MHz and less than about 10 MHz, e.g., about 3 MHz, is supplied from the second power supply 158 to the lower electrode 111. As a result, plasma of the processing gas is generated between the lower electrode 111 and the upper electrode 120 by the first high frequency power, and a self-bias potential is generated in the lower electrode 111 by the second high frequency power, so that the cleaning process for cleaning the inside of the processing chamber 102 can be carried out.

(Processing Gas for Use in the Cleaning Process)

In general, an O₂ gas may be used as a processing gas, and deposits may be eliminated by O₂ plasma. However, the O₂ plasma exhibits a low removing rate and it takes time to eliminate deposits by the O₂ plasma. Especially, since deposits adhered to the top of the periphery of the electrostatic chuck 112 as shown in FIG. 2 form a polymer (e.g., a CF polymer), it takes time to remove them.

To increase a removing rate of the deposits, it may be an easiest way to increase a self-bias voltage of the lower electrode 111 by increasing the high frequency powers applied to the electrodes or by minimizing an internal pressure of the processing chamber 102. In a wafer-less cleaning process performed without mounting a wafer W on the electrostatic chuck 112, however, the surface of the electrostatic chuck 112 may be exposed to plasma. Thus, since ion impact increases as the self-bias voltage of the lower electrode 111 increases, the surface of the electrostatic chuck 112 may be highly liable to be damaged.

To solve this problem, the present inventors have conducted various experiments and have found out that a removing rate can be increased without having to increase a self-bias voltage just by varying a flow rate ratio of a gaseous mixture of an O₂ gas and an inert gas (e.g., an Ar gas) as a processing gas for use in the cleaning process. By this method, a removing rate of deposits can be improved while damage on the surface of the electrostatic chuck 112 is suppressed.

To be more specific, the inventors conducted experiments to examine a relationship between a flow rate ratio of the O₂ gas and the inert gas and an internal pressure of the processing chamber 102, a first high frequency power (high frequency power for plasma generation) and a second high frequency power (high frequency power for bias voltage generation). An unexpected result was obtained.

In general, it has been believed that a removing rate of deposits would be reduced as a flow rate ratio of the inert gas is increased because a partial pressure of the O₂ gas would be reduced with the rise of the inert gas. In actual experiments, however, it was proved that in a certain internal pressure of the processing chamber or in a certain levels of the first and second high frequency powers, there exists a range in which the removing rate of the deposits increases even if the Ar gas is increased while the flow rate ratio of the O₂ gas is reduced.

Below, these experiment results will be explained with reference to the accompanying drawings. First, there will be discussed an experiment result showing a relationship between a flow rate ratio of a processing gas and a removing rate of deposits when an internal pressure of the processing chamber is varied. In this experiment, etching was performed for a wafer W having a diameter of about 300 mm and on which the same CF polymer as adhered to the lower electrode is formed. The etching was performed by using a gaseous mixture of an O₂ gas and an Ar gas as a processing gas under the same processing conditions as those for a cleaning process. Here, etching rates were measured as removing rates of deposits.

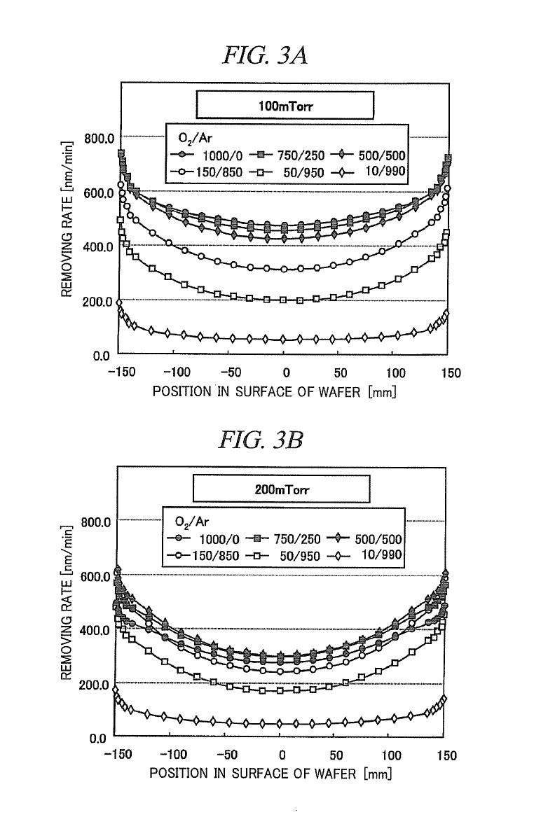

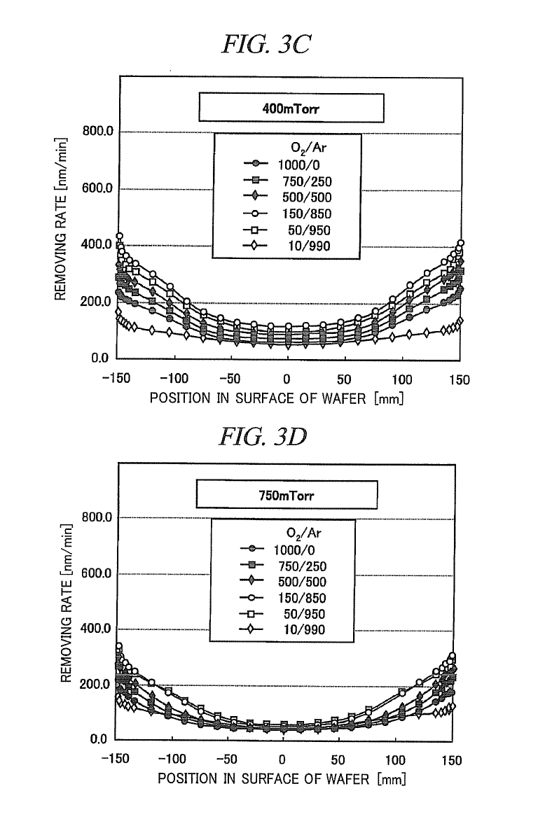

FIGS. 3A to 3D are graphs plotting removing rates of deposits measured while varying the flow rate ratio of the processing gas in respective cases where the internal pressure of the processing chamber was set to be about 100 mTorr, about 200 mTorr, about 400 mTorr and about 750 mTorr. A total flow rate of the processing gas was set to be about 1000 sccm, and etching (cleaning) was performed while varying a flow rate ratio between the O₂ gas and the Ar gas.

Specifically, in FIGS. 3A to 3D, etching was performed for respective cases where the flow rate ratio of O₂/Ar was set to be about 1000 sccm/0 sccm (O₂ gas: 100%), about 750 sccm/250 sccm (O₂ gas: 75%), about 500 sccm/500 sccm (O₂ gas: 50%), about 150 sccm/850 sccm (O₂ gas: 15%), about 50 sccm/950 sccm (O₂ gas: 5%) and about 10 sccm/990 sccm (O₂ gas: 1%) and removing rates were measured. Other processing conditions are as follows.

(Processing Conditions)

First high frequency power: 500 W

Second high frequency power: 0 W

Upper electrode temperature: 60° C.

Sidewall temperature: 60° C.

Lower electrode temperature: 40° C.

Processing time: 30 sec

When removing rates in surfaces of wafers W are observed from an overall point of view in FIGS. 3A to 3D, removing rates are found to decrease as the Ar gas is increased to reduce a flow rate ratio of the O₂ gas when the internal pressure of the processing chamber is about 100 mTorr and about 200 mTorr as shown in FIGS. 3A and 3B, respectively. Meanwhile, when the internal pressure is about 400 mTorr and about 750 mTorr as depicted in FIGS. 3C and 3D, removing rates are found to increase as the Ar gas is increased while reducing the flow rate ratio of the O₂ gas. Further, if the flow rate ratio of the O₂ gas is reduced, a removing rate at an edge portion of the wafer W is found to be higher than a removing rate at a center portion thereof. Thus, efficiency for removing deposits on the periphery of the electrostatic chuck 112 can be improved without incurring damage on a central portion thereof, which is deemed to be advantageous.

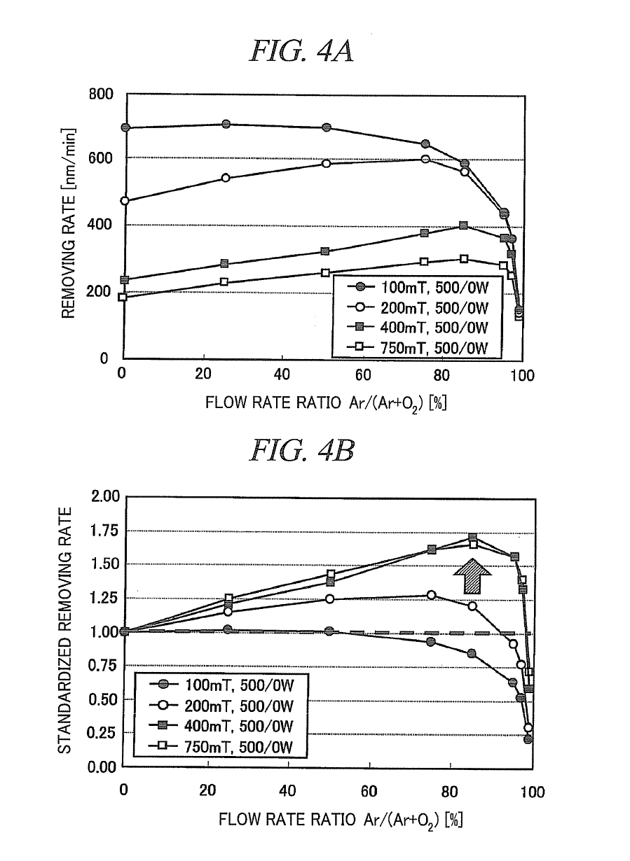

Here, FIGS. 4A and 4B are graphs in each of which a vertical axis indicates removing rates at edge portions of the wafers W of FIGS. 3A to 3D and a horizontal axis indicates a flow rate ratio of the processing gas. Since the horizontal axis in each of FIGS. 4A and 4B indicates the flow rate ratio of the processing gas as a percentage of Ar gas/(Ar gas+O₂ gas), a flow rate ratio of 0% implies that a flow rate ratio of the O₂ gas is about 100% while a flow rate ratio of 100% implies that the flow rate ratio of the O₂ gas is about 0%.

FIG. 4A is a graph showing a removing rate at a position 1 mm inward from an edge of a wafer W (a position of −149 mm in each of FIGS. 3A to 3D) at each pressure. FIG. 4B is a graph in which a removing rate at each flow rate ratio is standardized by a removing rate obtained when a flow rate ratio of the Ar gas is 0 (i.e., O₂ gas is 100%) in FIG. 4A. That is, FIG. 4B is a graph plotting values obtained by dividing removing rates at the respective flow rate ratios by the flow rate ratio obtained when the flow rate ratio of the Ar gas is 0 (i.e., O₂ gas is 100%). Further, in FIGS. 4A and 4B, experiment data obtained when the flow rate ratio of the O₂ gas/Ar gas is about 250 sccm/750 sccm (O₂ gas: 25%) and about 30 sccm/970 sccm (O₂ gas: 3%) are additionally provided.

As can be seen from FIGS. 4A and 4B, a removing rate at an edge of a wafer W is found to decrease as the Ar gas increases to reduce the flow rate ratio of the O₂ gas when the internal pressure is about 100 mTorr. Meanwhile, if the internal pressure is increased to about 200 mTorr, about 400 mTorr and about 750 mTorr, the removing rate is found to increase as the Ar gas increases while reducing the flow rate ratio of the O₂ gas. Especially, when the internal pressure is equal to or higher than about 400 mTorr, there is found a flow rate ratio that achieves a removing rate about 1.75 times as high as a removing rate obtained when the O₂ gas is 100%. Since, however, the removing rate may be deteriorated if the flow rate of the O₂ gas is excessively low, it may be desirable to use a flow rate ratio capable of achieving the maximum removing rate.

If the internal pressure of the processing chamber 102 is increased to about 200 mTorr, about 400 mTorr and about 750 mTorr, however, ion energy may be reduced. In such a case, it may be expected from the above experiment result that as the ion energy decreases, a removing rate may be increased if the Ar gas is increased while reducing the flow rate ratio of the O₂ gas. From this consideration, an experiment was conducted to verify this expectation.

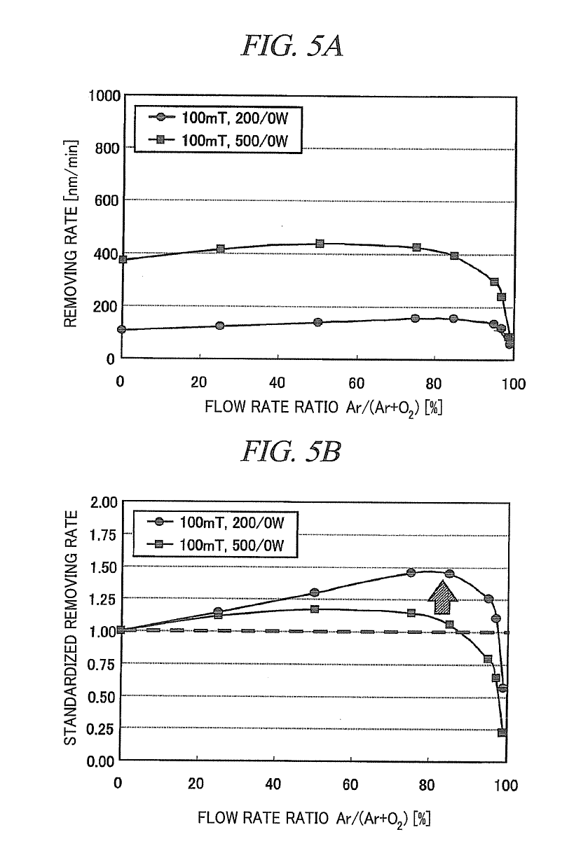

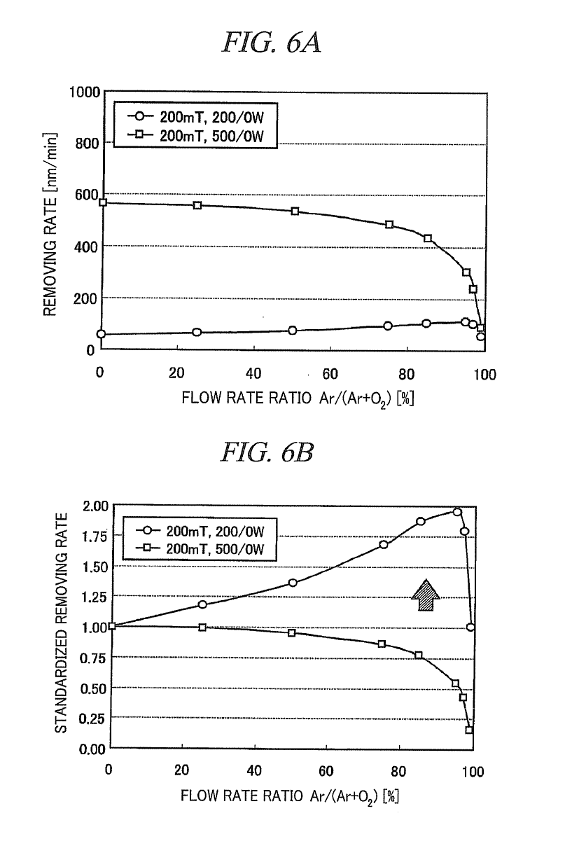

Here, there will be explained results of experiments conducted while varying a level of a first high frequency power applied to the lower electrode 111 under processing conditions in which a removing rate did not increase as much as the flow rate of the Ar gas was increased, i.e., when the internal pressure of the processing chamber was set to be about 100 mTorr and about 200 mTorr, respectively. To elaborate, the same experiments as in FIGS. 3A (100 mTorr) and 3B (200 mTorr) were conducted while varying the first high frequency power when a second high frequency power was fixed at about 0 W. FIGS. 5A and 5B are graphs in each of which a vertical axis indicates a removing rate at an edge (a position of −149 mm) of a wafer W and a horizontal axis indicates a flow rate ratio of the processing gas, as in FIGS. 4A and 4B, when the internal pressure was about 100 mTorr. Further, FIGS. 6A and 6B are graphs in each of which a vertical axis indicates a removing rate at an edge (a position of −149 mm) of a wafer W and a horizontal axis indicates a flow rate ratio of the processing gas, as in FIGS. 4A and 4B, when the internal pressure was about 200 mTorr.

As can be seen from FIGS. 5A and 5B and 6A and 6B, in both cases where the internal pressure of the processing chamber is about 100 mTorr and about 200 mTorr, an increment of a removing rate is found to increase if the Ar is increased while reducing the flow rate ratio of the O₂ gas when the first high frequency power is reduced to about 200 W from about 500 W. In FIGS. 6A and 6B, an increment of a removing rate is shown to increase remarkably when the internal pressure is about 200 mTorr. In view of this result, it is proved that the effect of increasing the Ar gas tends to be exerted as in the cases of FIG. 3C (400 mTorr) and FIG. 3D (750 mTorr) if the ion energy is reduced by decreasing the first high frequency power.

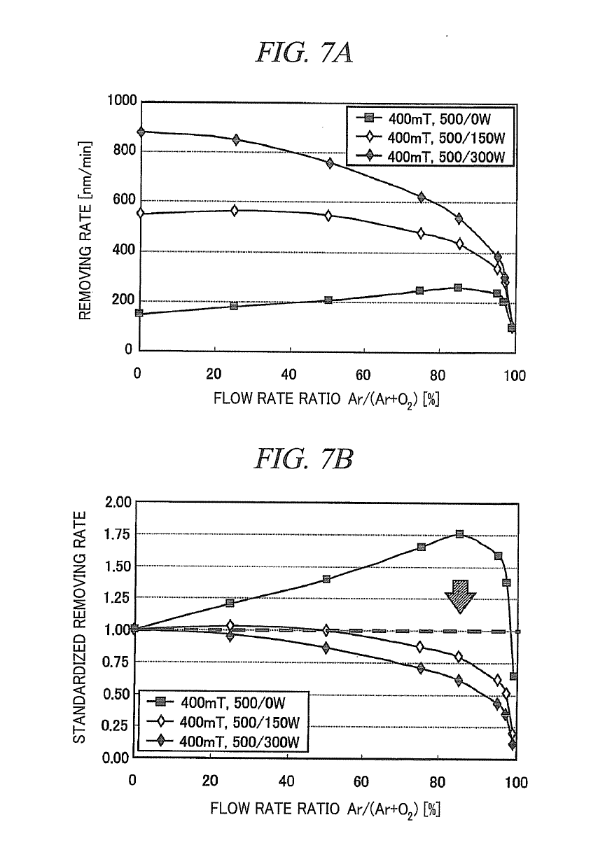

Now, there will be described a result of experiment of increasing ion energy by increasing the second high frequency power applied to the lower electrode 111, which was performed under a condition in which a removing rate increased with the rise of the flow rate of the Ar gas, i.e., when the internal pressure of the processing chamber was about 400 mTorr. To be specific, the same experiment as in FIG. 3C (400 mTorr) was performed while varying a level of the second high frequency power when the first high frequency power was fixed at about 500 W. FIGS. 7A and 7B are graphs in each of which a vertical axis represents a removing rate at an edge (position of −149 mm) of a wafer W and a horizontal axis indicates a flow rate ratio of the processing gas.

As can be seen from FIGS. 7A and 7B, if ion energy is increased by increasing the second high frequency power to about 150 W and to about 300 W, a removing rate does not increase even if the Ar gas is increased while reducing the flow rate ratio of the O₂ gas, as compared to the case of applying the second high frequency power of about 0 W. Accordingly, it is found out that the effect of increasing the Ar gas tends to be weakened when the internal pressure of the processing chamber is about 400 mTorr, the same as in the case of FIG. 3A (100 mTorr) or FIG. 3B (200 mTorr).

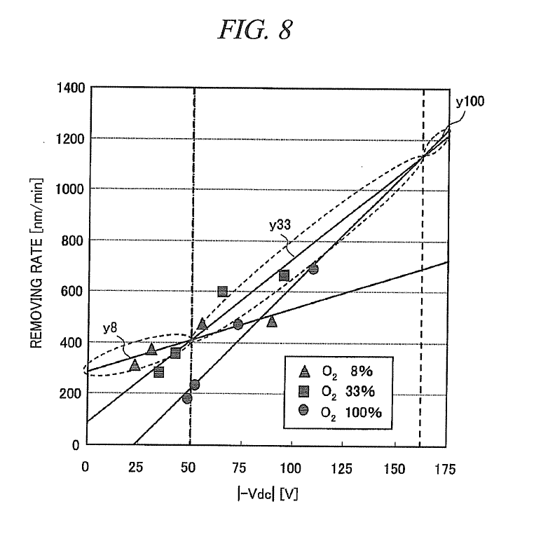

From the above-described experiment results, it is found out that a flow rate ratio of Ar gas/O₂ gas capable of increasing a removing rate of deposits is closely related with ion energy. Since the ion energy is proportional to a magnitude of a self-bias voltage (−Vdc) of the lower electrode, a relationship between the self-bias voltage (−Vdc) and the removing rate of deposits was investigated based on the above-described experiment results. FIG. 8 is a graph showing such a relationship.

A flow rate ratio of the processing gas suitable for increasing a removing rate was selected in each of the above-described experiment results, and a self-bias voltage (−Vdc) at the selected flow rate ratio was obtained. FIG. 8 is a graph in which a horizontal axis indicates an absolute value of the self-bias voltage (−Vdc) and a vertical axis indicates a removing rate of deposits. To elaborate, the flow rate ratio of the processing gas was selected within a range in which the removing rate could be maximized based on the experiment results of FIGS. 4A and 4B and so forth. Here, data obtained by the experiments for acquiring removing rates when a flow rate ratio of the O₂ gas to the entire processing gas including the O₂ gas and the Ar gas was about 8%, about 33%- and about 100% were used.

In FIG. 8, if plot data in the respective cases where the O₂ gas was about 8%, about 33% and about 100% are approximated in straight lines, straight lines y8, y33 and y100 are obtained. These straight lines y8, y33 and y100 have different inclinations. Among the straight lines y8, y33 and y100, a straight line in a higher position means a higher removing rate. However, a straight line in a highest position may be varied depending on a range of the self-bias voltage. Thus, it can be found out that the flow rate ratio of the processing gas suitable for increasing the removing rate may vary depending on the range of the self-bias voltage.

By way of example, when an absolute value of the self-bias voltage (−Vdc) is equal to or larger than about 160 V, the straight line y100 is located at an uppermost position, which implies that the removing rate can be maximized when the flow rate ratio of the O₂ gas is about 100%. On the other hand, when an absolute value of the self-bias voltage (−Vdc) is between about 50 V and about 160 V, the straight line y33 is located at an uppermost position, which implies that the removing rate can be maximized when the flow rate ratio of the O₂ gas is about 33%. Further, when an absolute value of the self-bias voltage (−Vdc) is equal to or less than 50 V, the straight line y8 is located at an uppermost position, which implies that the removing rate can be maximized when the flow rate of the O₂ gas is about 8%.

As discussed, the reason why the removing rate of deposits can be improved by increasing the Ar gas while reducing the flow rate ratio of the O₂ gas even in a case of a small self-bias voltage is deemed to be as follows in consideration of, e.g., plasma density. Since the Ar gas is capable of consuming energy in ionization, the Ar gas may be easily ionized, whereas the O₂ gas requires a great amount of energy even when the O₂ gas is dissociated into oxygen radicals. Thus, plasma density may not be increased only with the O₂ gas. Accordingly, although it may become more difficult to acquire a high removing rate as the consumption of the Ar gas increases because the self-bias voltage decreases, the number of Ar ions may be increased, and ion density or electron density may be enhanced. Thus, dissociation of the O₂ gas can be facilitated. Therefore, in a range where the self-bias voltage is small, a deposit removing efficiency is deemed to be increasable by increasing the Ar gas because ionization of the O₂ gas can be facilitated in such a case.

In view of the foregoing, when the inside of the processing chamber 102 is cleaned under preset processing conditions in the cleaning process in accordance with the present disclosure, the processing gas containing the O₂ gas and the Ar gas is supplied into the processing chamber 102 at a flow rate ratio set depending on the self-bias voltage of the lower electrode 111. Here, the flow rate ratio of the processing gas is set such that the flow rate ratio of the O₂ gas decreases while the flow rate ratio of the Ar gas increases as an absolute value of the self-bias voltage of the lower electrode 111 decreases. Then, by applying a high frequency power between the electrodes, plasma of the processing gas is generated.

To be more specific, under a processing condition in which an absolute value of the self-bias voltage (−Vdc) is equal to or less than about 50 V, a flow rate ratio between the O₂ gas and the Ar gas is set such that the flow rate ratio of the O₂ gas becomes equal to or higher than about 8% and less than about 33%. Further, under a processing condition in which the absolute value of the self-bias voltage (−Vdc) is larger than about 50 V and smaller than about 160 V, a flow rate ratio between the O₂ gas and the Ar gas is set such that the flow rate ratio of the O₂ gas becomes equal to or higher than about 33% and less than about 100%. These flow rate ratios of the processing gas may be previously stored in the storage unit 164 together with other processing conditions and may be read out therefrom to be used.

As discussed above, the present inventors have found out that there is a certain relationship between the self-bias voltage (−Vdc) and the flow rate ratio of the processing gas and also found out that the removing rate of deposits can be increased just by changing the flow rate ratio of the processing gas for use in the cleaning process depending on the self-bias voltage (−Vdc).

Thus, since the removing rate of the deposits can be increased without increasing the self-bias voltage (−Vdc), time required to eliminate deposits adhered to the periphery of the electrostatic chuck 112 can be shortened while suppressing damage on the surface of the electrostatic chuck 112.

Further, under a processing condition in which the absolute value of the self-bias voltage is equal to or greater than about 160 V, it may be desirable to set the flow rate ratio between the O₂ gas and the Ar gas such that the O₂ gas becomes about 100%. To achieve the effect of improving the removing rate by increasing Ar gas while also suppressing damage on the surface of the mounting table 110 (i.e., on the surface of the electrostatic chuck 112), it may be desirable to perform the cleaning process under a processing condition in which the absolute value of the self-bias voltage is within a range smaller than about 160 V or about 50 V.

Further, although the above embodiment has been described for the case of using the Ar gas as an inert gas added to the O₂ gas as the processing gas for the cleaning process, the inert gas is not limited to the Ar gas. By way of example, an inert gas such as a He gas, a Ne gas or a Kr gas may be used instead of the Ar gas.

Further, a medium such as a storage medium storing therein a software program for implementing the functions of the aforementioned embodiment may be provided to a system or an apparatus, and the program stored in the medium such as the storage medium may be read out and executed by a computer (CPU or a MPU) of the system or the apparatus, so that the present disclosure may be implemented.

In such a case, the program itself read out from the medium such as the storage medium may implement the functions of the aforementioned embodiment, and the present disclosure may be embodied by the medium such as the storage medium storing therein the program. By way of example, the medium such as the storage medium for supplying the program may be a floppy (registered trademark) disk, a hard disk, an optical disk, a magneto-optical disk, a CD-ROM, a CD-R, a CD-RW, a DVD-ROM, a DVD-RAM, a DVD-RW, a DVD+RW, a magnetic tape, a nonvolatile memory card, a ROM, or the like. Alternatively, the program may be downloaded into the medium through a network.

Furthermore, the present disclosure includes not only a case in which the functions of the aforementioned embodiment are implemented by executing the program read out by the computer but also a case in which an OS (Operating System) or the like operated on the computer executes a part or all of actual processes based on instructions of the program such that the functions of the aforementioned embodiment can be implemented by these processes.

Moreover, the present disclosure also includes a case in which the program read from the storage medium is written in a memory provided in a function extension board inserted into the computer or in a function extension unit connected to the computer, and then a CPU or the like included in the extension board or the extension unit executes a part or all of the actual processes based on instructions of the program such that the functions of the aforementioned embodiment can be implemented by these processes.

While various aspects and embodiments have been described herein, other aspects and embodiments will be apparent to those skilled in the art. The various aspects and embodiments disclosed herein are for the purposes of illustration and are not intended to be limiting. Therefore, the true scope of the disclosure is indicated by the appended claims rather than by the foregoing description, and it shall be understood that all modifications and embodiments conceived from the meaning and scope of the claims and their equivalents are included in the scope of the disclosure.

By way of example, although the present embodiment has been described for the case of using the plasma processing apparatus that generates plasma by applying two kinds of high frequency powers only to the lower electrode, the type of the plasma processing apparatus is not limited thereto. For instance, the plasma processing apparatus may be of a type that applies a single high frequency power only to a lower electrode or may be of a type that applies two different kinds of high frequency powers to an upper electrode and a lower electrode, respectively. Further, a substrate processing apparatus to which the present disclosure is applicable is not limited to a plasma processing apparatus but may be a heat treating apparatus that performs a film forming process.

The present disclosure has many advantages when it is applied to a substrate processing apparatus for cleaning the inside of a processing chamber having therein a substrate mounting table for mounting thereon a substrate such as a semiconductor wafer or a FPD substrate. The present disclosure is also applicable to a cleaning method of the substrate processing apparatus and a storage medium storing therein a program.

What is claimed is:

1. A cleaning method for a substrate processing apparatus for cleaning the inside of an evacuable processing chamber including an upper electrode and a substrate mounting table having a lower electrode installed so as to face the upper electrode, the cleaning method comprising:
supplying, to clean the inside of the processing chamber under preset processing conditions, a processing gas including an O₂ gas and an inert gas into the processing chamber at a preset flow rate ratio of the processing gas; and
generating plasma of the processing gas by applying a high frequency power between the electrodes,
wherein the flow rate ratio of the processing gas is set depending on a self-bias voltage of the lower electrode such that a flow rate ratio of the O₂ gas is reduced while a flow rate ratio of the inert gas is increased as an absolute value of the self-bias voltage decreases.

2. The cleaning method of claim 1, wherein the inert gas is an Ar gas, and
the flow rate ratio of the O₂ gas and the inert gas is set such that the flow rate ratio of the O₂ gas is equal to or higher than about 8% and less than about 33% of the entire processing gas when the cleaning is performed under a processing condition that the absolute value of the self-bias voltage is equal to or less than about 50 V.

3. The cleaning method of claim 2, wherein the flow rate ratio of the O₂ gas and the inert gas is set such that the flow rate ratio of the O₂ gas is equal to or higher than about 331 and less than about 1001 of the entire processing gas when the cleaning is performed under a processing condition that the absolute value of the self-bias voltage is more than about 50 V and less than about 160 V.

4. A substrate processing apparatus comprising:
an evacuable processing chamber;
an upper electrode and a lower electrode installed in the processing chamber so as to face each other;
a substrate mounting table including the lower electrode;
a power supply unit that supplies a preset high frequency power between the electrodes;
a gas supply unit that supplies an O₂ gas and an inert gas into the processing chamber as a processing gas for cleaning;
a gas exhaust unit that evacuates the processing chamber and depressurizes the inside of the processing chamber to a preset pressure;
a storage unit that stores therein a flow rate ratio of the processing gas set depending on a self-bias voltage of the lower electrode such that a flow rate ratio of the O₂ gas is reduced while a flow rate ratio of the inert gas is increased as an absolute value of the self-bias voltage decreases when the inside of the processing chamber is cleaned under preset processing conditions; and
a controller that reads out the flow rate ratio corresponding to a self-bias voltage from the storage unit when the inside of the processing chamber is cleaned, supplies the O₂ gas and the inert gas from the gas supply unit at the read-out flow rate ratio and generates plasma by applying a preset high frequency power between the electrodes from the power supply unit.

5. The cleaning method of claim 4, wherein the inert gas is an Ar gas, and
flow rate ratio of the O₂ gas and the inert gas is set such that the flow rate ratio of the O₂ gas is equal to or higher than about 8% and less than about 33% of the entire processing gas is stored in the storage unit when the cleaning is performed under a processing condition that the absolute value of the self-bias voltage is equal to or less than about 50 V.

6. The cleaning method of claim 5, wherein flow rate ratio of the O₂ gas and the inert gas is set such that the flow rate ratio of the O₂ gas is equal to or higher than about 33% and less than about 100% of the entire processing gas is stored in the storage unit when the cleaning is performed under a processing condition that the absolute value of the self-bias voltage is more than about 50 V and less than about 160 V.
